(19) United States
(12) Patent Application Publication
(10) Pub. No.: US 2009/0251179 A1
(43) Pub. Date: Oct. 8, 2009

(54) CLOCK DISABLING CIRCUIT AND CLOCK SWITCHING DEVICE UTILIZING THE SAME

(75) Inventor: Yung-Chih Yen, Tainan City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/098,477

(22) Filed: Apr. 7, 2008

(51) Int. Cl. H03L 7/00

(52) U.S. Cl. 327/153

(57) ABSTRACT

A clock disabling circuit includes a control unit, an OR gate, and a first AND gate. The control unit generates a first delay signal by delaying a selected enable signal when the selected enable signal is at a first level. The control unit generates a second delay signal by delaying the selected enable signal or by directly outputting the selected enable signal when the selected enable signal is at a second level. Delays of the first delay signal and the second delay signal are different. The OR gate generates an intermediate signal according to an output of the control unit and a processing signal. The first AND gate generates the processing signal according to the intermediate signal and a clock signal. A clock switching device and method and a clock disabling method are also disclosed.

### BACKGROUND OF THE INVENTION

1. Field of the Invention

The invention relates to a circuit, and more particularly to a clock disabling circuit and a clock switching device.

2. Description of the Related Art

FIG. 1a is a schematic diagram of a conventional clock switching device. The conventional clock switching device 100 comprises a multiplexer 110, which selectively outputs one of the clock signals ck1 and ck2 to generate an output signal ck_out. FIG. 1b is a timing chart of signals of the conventional clock switching device 100. The output signal ck_out is equal to clock signal ck2 when a select signal ck_sel is at a low logic level, and the output signal ck_out is equal to clock signal ck1 when the select signal ck_sel is at a high logic level. An unexpected glitch often occur during the transition of the select signal ck_sel, such as from the low logic level to the high logic level or from the high logic level to the low logic level, which may shorten the pulse width of the output signal ck_out, thus causing setup time violation of the digital circuit so as to make the function failed.

### BRIEF SUMMARY OF THE INVENTION

Clock disabling circuits are provided. An exemplary embodiment of a clock disabling circuit comprises a control unit, an OR gate, and a first AND gate. The control unit is arranged to generate a first delay signal by delaying a selected enable signal when the selected enable signal is at a first level. The control unit is arranged to generate a second delay signal by delaying the selected enable signal or by directly outputting the selected enable signal when the selected enable signal is at a second level. Delays of the first delay signal and the second delay signal are different. The OR gate is arranged to generate an intermediate signal according to an output of the control unit and a processing signal. The first AND gate is arranged to generate the processing signal according to the intermediate signal and a clock signal.

Clock switching devices are provided. An exemplary embodiment of a clock switching device comprises a first clock disabling circuit, a second clock disabling circuit, and a third OR gate. The first clock disabling circuit comprises a first control unit, a first OR gate, and a first AND gate. The first control unit is arranged to generate a first delay signal by delaying a first selected enable signal when the first selected enable signal is at a first level. The first control unit is arranged to generate a second delay signal by delaying the first selected enable signal or by directly outputting the first selected enable signal when the first selected enable signal is at a second level. Delays of the first delay signal and the second delay signal are different. The first OR gate is arranged to generate a first intermediate signal according to an output of the first control unit and a first processing signal. The first AND gate is arranged to generate the first processing signal according to the first intermediate signal and a first clock signal. The second clock disabling circuit comprises a second control unit, a second OR gate, and a second AND gate. The second control unit is arranged to generate a third delay signal by delaying a second selected enable signal when the second selected enable signal is at the first level. The second control unit is arranged to generate a fourth delay signal by delaying the second selected enable signal or by directly outputting the second selected enable signal when the second selected enable signal is at the second level. Delays of the third delay signal and the fourth delay signal are different. The second OR gate is arranged to generate a second intermediate signal according to an output of the second control unit and a second processing signal. The second AND gate is arranged to generate the second processing signal according to the second intermediate signal and a second clock signal. The third OR gate receives the first and the second processing signals to generate an output signal.

Clock disabling methods are provided. An exemplary embodiment of a clock disabling method comprises generating a first delay signal by delaying a selected enable signal when the selected enable signal is at a first level; generating a second delay signal by delaying the selected enable signal or by directly outputting the selected enable signal when the selected enable signal is at a second level, wherein delays of the first delay signal and the second delay signal are different; generating an intermediate signal according to a processing signal and a result produced from the steps of generating a first delay signal and a second delay signal; and generating the processing signal according to the intermediate signal and a clock signal.

Clock switching methods are provided. An exemplary embodiment of a clock switching method comprises generating a first delay signal by delaying a first selected enable signal when the first selected enable signal is at a first level; generating a second delay signal by delaying the first selected enable signal or by directly outputting the first selected enable signal when the first selected enable signal is at a second level, wherein delays of the first delay signal and the second delay signal are different; generating a first intermediate signal according to a first processing signal and a result produced from the steps of generating a first delay signal and a second delay signal; generating the first processing signal according to the first intermediate signal and a first clock signal; generating a third delay signal by delaying a second selected enable signal when the second selected enable signal is at the first level; generating a fourth delay signal by delaying the second selected enable signal or by directly outputting the second selected enable signal when the second selected enable signal is at the second level, wherein delays of the third delay signal and the fourth delay signal are different; generating a second intermediate signal according to a second processing signal and a result produced from the steps of generating a third delay signal and a fourth delay signal; generating the second processing signal according to the second intermediate signal and a second clock signal; and generating an output signal according to the first processing signal and the second processing signal.

A detailed description is given in the following embodiments with reference to the accompanying drawings.

### BRIEF DESCRIPTION OF THE DRAWINGS

The invention can be more fully understood by referring to the following detailed description and examples with references made to the accompanying drawings, wherein:

FIG. 1a is a schematic diagram of a conventional clock switching device;

FIG. 1b is a timing chart of signals of the conventional clock switching device 100;

FIG. 2 is a schematic diagram of an exemplary embodiment of a clock switching device;

FIG. 3a is a schematic diagram of an exemplary embodiment of the control unit;

FIG. 3b is a schematic diagram of an exemplary embodiment of the delay module;

FIGS. 4a and 4b are timing charts of signals of the clock disabling circuits 210 and 220;

FIG. 4c is a timing chart of signals of the clock switching device 200;

FIG. 5 is a schematic diagram of an exemplary embodiment of enable units;

FIG. 6a is a schematic diagram of another exemplary embodiment of the control unit;

FIG. 6b is a schematic diagram of another exemplary embodiment of the delay module;

FIG. 7 is a timing chart of signals of the delay module 610;

FIG. 8 is a schematic diagram of an exemplary embodiment of a clock switching circuit;

FIG. 9 is a flowchart of an exemplary embodiment of a clock disabling method;

FIG. 10 is a flowchart of an exemplary embodiment of delaying the selected enable signal; and

FIG. 11 is a flowchart of an exemplary embodiment of a clock switching method.

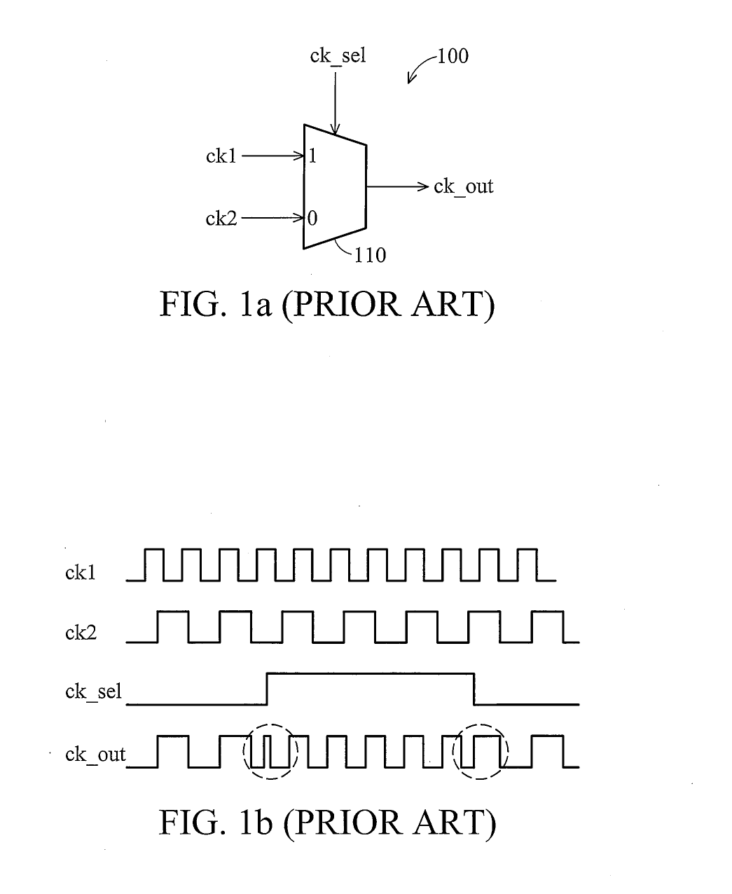

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

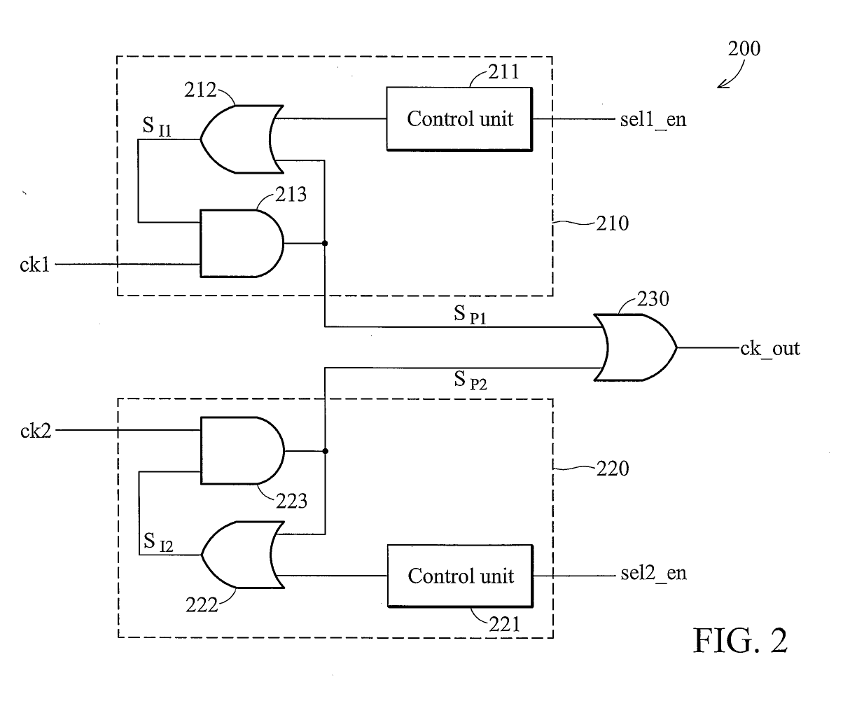

FIG. 2 is a schematic diagram of an exemplary embodiment of a clock switching device. Clock switching device 200 comprises clock disabling circuits 210, 220, and an OR gate 230. Clock disabling circuit 210 generates a processing signal S_{P1} according to a selected enable signal sel1_en and a clock signal ck1. Clock disabling circuit 220 generates a processing signal S_{P2} according to a selected enable signal sel2_en and a clock signal ck2. OR gate 230 generates an output signal ck_out according to processing signals S_{P1} and S_{P2}. In some embodiments, OR gate 230 provides output signal ck_out to a principal digital circuit (not shown).

Assuming clock signal ck1 is provided by a main clock generator and clock signal ck2 is provided by a sub-clock generator. For example, the sub-clock generator, e.g. a free-run ring oscillator, is arranged to provisionally provide clock signal ck2 for serving as the output signal ck_out when the main clock generator, e.g. a temperature controlled crystal oscillator (TCXO), is not ready to provide clock signal ck1 of a precision clock. However, when the main clock generator gets ready to provide clock signal ck1, such as after warming-up, the output signal ck_out will be switched to clock signal ck1.

Clock disabling circuit 210 comprises control unit 211, OR gate 212, and AND gate 213. When selected enable signal sel1_en is at a first level, e.g. a high logic level, control unit 211 delays selected enable signal sel1_en to generate a first delay signal and outputs the first delay signal. In one example, when selected enable signal sel1_en is at a second level, e.g. a low logic level, control unit 211 delays selected enable signal sel1_en to generate a second delay signal and outputs the second delay signal. Delays of the first delay signal and the second delay signal are different. Alternatively, according to another embodiment, when selected enable signal sel1_en is at the second level, control unit 211 may directly output selected enable signal sel1_en, which serves as the second delay signal with substantially no delay in this case. OR gate 212 receives the output signal from control unit 211 and processing signal S_{P1} to generate an intermediate signal S_{I1}. AND gate 213 receives the intermediate signal S_{I1} and clock signal ck1 to generate processing signal S_{P1}.

Similarly, clock disabling circuit 220 comprises control unit 221, OR gate 222, and AND gate 223. When selected enable signal sel2_en is at the first level, e.g. the high logic level, control unit 221 delays selected enable signal sel2_en to generate a third delay signal and outputs the third delay signal. In one example, when selected enable signal sel2_en is at the second level, e.g. the low logic level, control unit 221 delays selected enable signal sel2_en to generate a fourth delay signal and then outputs the fourth delay signal. Delays of the third delay signal and the fourth delay signal are different. Alternatively, according to another embodiment, when selected enable signal sel2_en is at the second level, control unit 221 may directly output selected enable signal sel2_en, which serves as the fourth delay signal with substantially no delay in this case. OR gate 222 receives the output signal output from control unit 221 and processing signal S_{P2} to generate intermediate signal S_{I2}. AND gate 223 receives the intermediate signal S_{I2} and clock signal ck2 to generate processing signal S_{P2}.

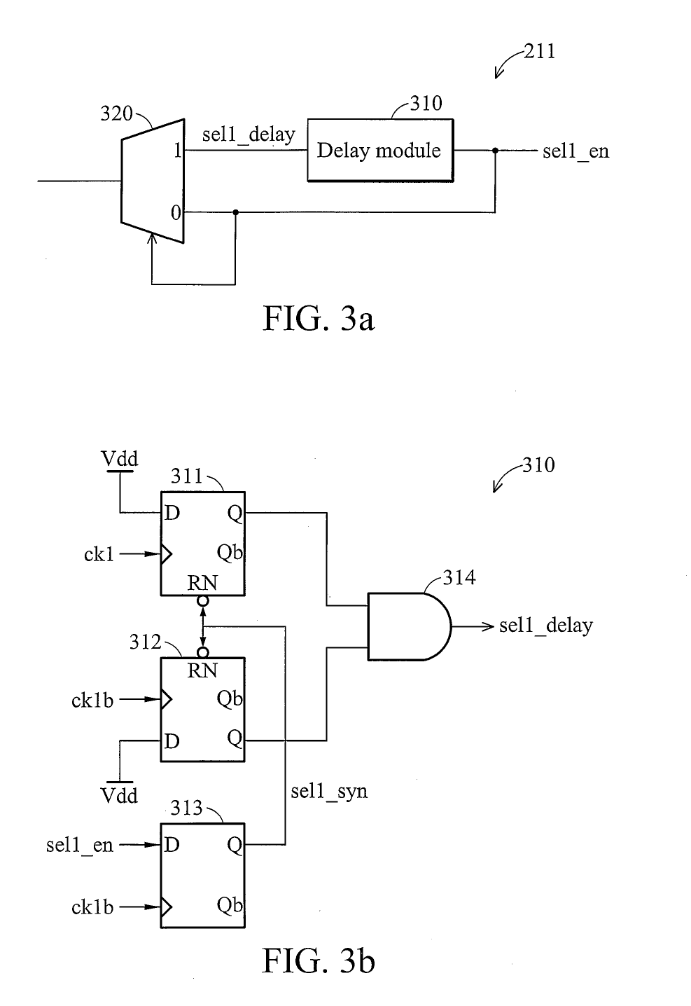

Since the operations of clock disabling circuits 210 and 220 are the same, clock disabling circuit 210 is given as an example. FIG. 3a is a schematic diagram of an exemplary embodiment of the control unit. Control unit 210 comprises delay module 310 and multiplexer 320. Delay module 310 delays selected enable signal sel1_en to generate the first delay signal sel1_delay. Multiplexer 320 outputs one of selected enable signal sel1_en and the first delay signal sel1_delay according to the selected enable signal sel_en. In this embodiment, when selected enable signal sel1_en is at the first level, such as the high logic level, multiplexer 320 outputs the first delay signal sel1_delay to OR gate 212. When selected enable signal sel1_en is at the second level, such as the low logic level, multiplexer 320 outputs selected enable signal sel1_en to OR gate 212.

FIG. 3b is a schematic diagram of an exemplary embodiment of the delay module. Delay module 310 comprises flip-flops 311˜313 and AND gate 314. Flip-flop 311 selectively outputs the voltage signal Vdd according to clock signal ck1. Flip-flop 312 selectively outputs the voltage signal Vdd according to an inversed clock signal ck1b inverse to clock signal ck1. Flip-flop 313 generates a synchronization signal sel1_sync by selectively outputting selected enable signal sel1_en according to inversed clock signal ck1b. The synchronization signal sel1_syn is provided for resetting flip-flops 311 and 312. AND gate 314 generates the first delay signal sel1_delay according to the outputs of flip-flops 311 and 312. In this embodiment, flip-flops 311˜313 are D-type flip-flops. When a D-type flip-flop is reset, the output terminal of the D-type flip-flop is at a low logic level. In some embodiments, the D-type flip-flop is replaced by other kind of flip-flop, such as J-K flip-flop.

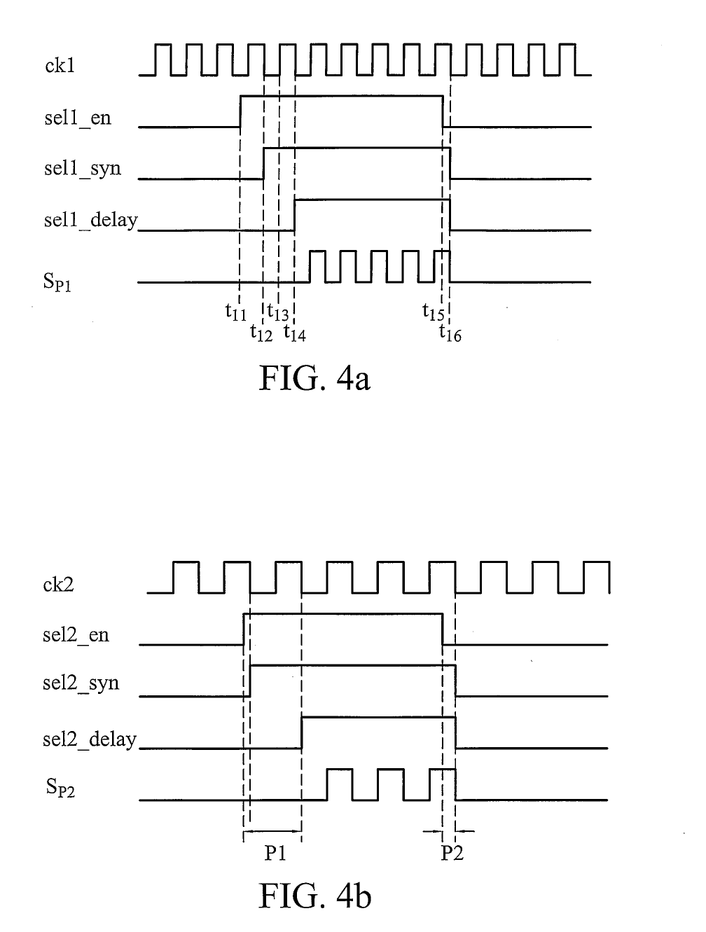

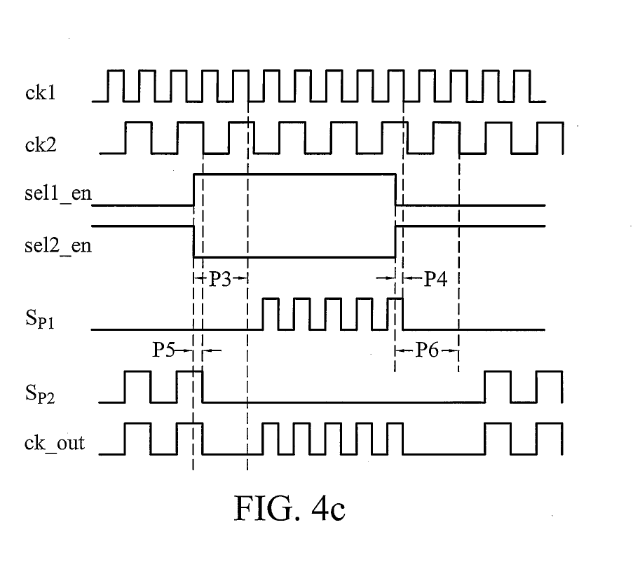

FIG. 4a is a timing chart of signals of the clock disabling circuit 210. Reference with FIG. 2, before a time point t₁₁, selected enable signal sel1_en is at the low logic level such that processing signal S_{P1} is at the low logic level. At the time point t₁₁, selected enable signal sel1_en is changed from the low logic level to the high logic level such that control unit 211 delays selected enable signal sel1_en to generate the first delay signal sel1_delay and outputs the first delay signal sel1_delay to OR gate 212. A more detailed description of the first delay signal sel1_delay follows.

During the period between time points t₁₁ and t₁₄, the first delay signal sel1_delay is at the low logic level such that processing signal S_{P1} is also at the low logic level. During the period between time points t₁₄ and t₁₆, the first delay signal sel1_delay is at the high logic level such that processing signal S_{P1} is approximately equal to clock signal ck1. At time point t₁₆, the first delay signal sel1_delay and clock signal ck1 are at the low logic level such that processing signal S_{P1} is also at the low logic level.

Referring to FIG. 3b, before time point t₁₁, synchronization signal sel1_syn is at the low logic level because selected enable signal sel1_en is at the low logic level. During the period between time points t₁₁ and t₁₂, clock signal ck1 is not changed from the high logic level to the low logic level such that synchronization signal sel1_syn is still at the low logic level. At time point t₁₂, inversed clock signal ck1b, which is inverse to clock signal ck1, is changed from the low logic level to the high logic level so as to trigger flip-flop 313, and thus, synchronization signal sel1_syn is changed from the low logic level to the high logic level.

At time point t₁₃, clock signal ck1 is changed from the low logic level to the high logic level so as to trigger flip-flop 311. Thus, the output of flip-flop 311 is at the high logic level. Since flip-flop 312 is not triggered, the output of flip-flop 312 is at the low logic level. Thus, first delay signal sel1_delay generated by AND gate 314 is still at the low logic level at time point t₁₃.

At time point t₁₄, inversed clock signal ck1b, which is inverse to clock signal ck1, is changed from the low logic level to the high logic level so as to trigger flip-flop 312. Thus, the output of flip-flop 312 is at the high logic level such that first delay signal sel1_delay generated by AND gate 314 is changed from the low logic level to the high logic level.

At time point t₁₅, selected enable signal sel1_en is changed from the high logic level to the low logic level. At time point t₁₆, inversed clock signal ck1b, which is inverse to clock signal ck1, is changed from the low logic level to the high logic level so as to trigger flip-flop 313. Thus, synchronization signal sel1_syn is at the low logic level such that flip-flops 311 and 312 are reset and first delay signal sel1_delay is changed from the high logic level to the low logic level.

FIG. 4b is a timing chart of signals of the clock disabling circuit 220. When selected enable signal sel2_en is at the low logic level, processing signal S_{P2} is at the low logic level. When selected enable signal sel2_en is changed from the low logic level to the high logic level, processing signal S_{P2} is approximately equal to clock signal ck2 after period P1. When selected enable signal sel2_en is changed from the high logic level to the low logic level, processing signal S_{P2} is changed from the high logic level to the low logic level after period P2. Since processing signals S_{P1} and S_{P2} have the same operating principle, description of processing signal S_{P2} is omitted for brevity.

FIG. 4c is a timing chart of signals of the clock switching device 200, especially illustrating the output signal ck_out generated according to processing signals S_{P1} and S_{P2}. When selected enable signal sel1_en is changed from the low logic level to the high logic level, processing signal S_{P1} is approximately equal to clock signal ck1 after period P3. When selected enable signal sel1_en is changed from the high logic level to the low logic level, processing signal S_{P1} is approximately equal to the low logic level after period P4. Similarly, when selected enable signal sel2_en is changed from the high logic level to the low logic level, processing signal S_{P2} is approximately equal to the low logic level after period P5. When selected enable signal sel2_en is changed from the low logic level to the high logic level, processing signal S_{P2} is approximately equal to clock signal ck2 after period P6. Referring to FIG. 2, OR gate 230 generates output signal ck_out shown in FIG. 4c according to processing signals S_{P1} and S_{P2}. When selected enable signal sel1_en or sel2_en is changed, the pulse width of output signal ck_out, between any-two rising edges or falling edges is not excessively short, that is, without unexpected glitch. Additionally, selected enable signals sel1_en and sel2_en are inverse in this example, and thus, an inverter (not shown) is utilized. The inverter may invert selected enable signal sel1_en to generate selected enable signal sel2_en.

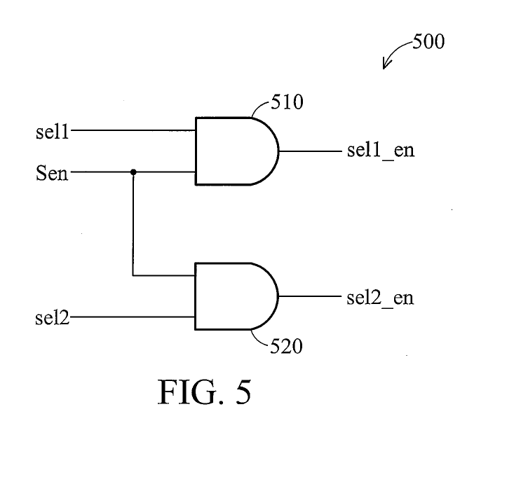

Alternatively, the two selected enable signals sel1_en and sel2_en can be generated by another way. FIG. 5 is a schematic diagram of an example for a generator which is provided for generating selected enable signals. Generator 500 comprises enable units 510 and 520. Enable unit 510 generates selected enable signal sel1_en according to a select signal sel1 and an enable signal Sen. Enable unit 520 generates selected enable signal sel2_en according to a select signal sel2 and the enable signal Sen. In this embodiment, enable units 510 and 520 are AND gates.

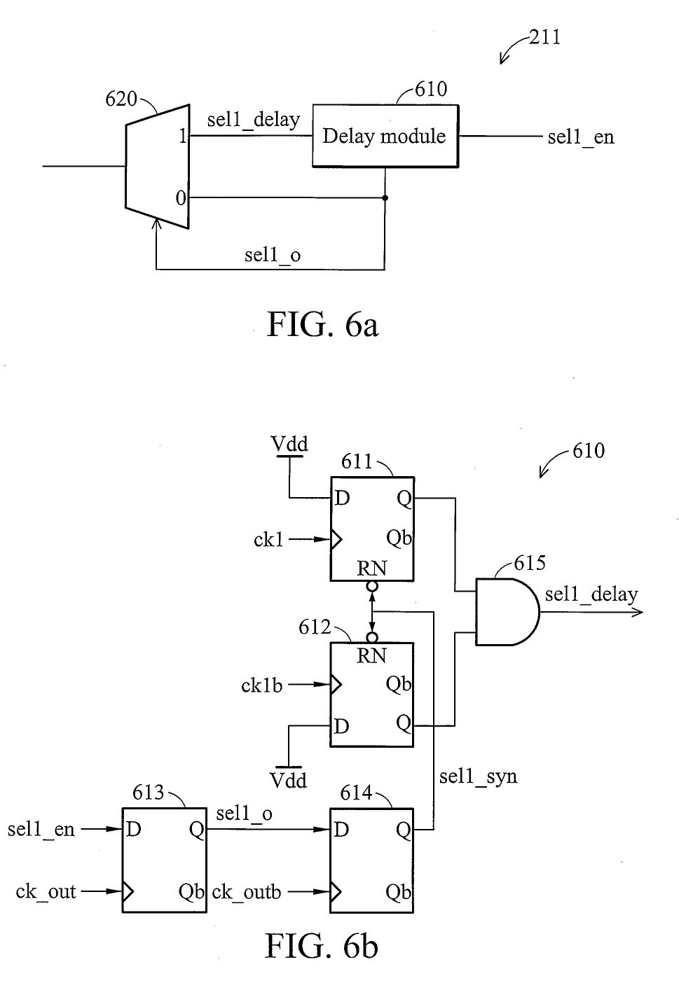

FIG. 6a is a schematic diagram of another exemplary embodiment of the control unit. Control unit 211 comprises delay module 610 and multiplexer 620. Delay module 610 delays selected enable signal sel1_en to generate the first delay signal sel1_delay and the second delay signal sel1_o. Delays of the first delay signal sel1_delay and the second delay signal sel1_o are different, for example, the first delay signal sel1_delay is delayed from the second delay signal sel1_o for a predetermined period. Multiplexer 620 outputs one of the first delay signal sel1_delay and the second delay signal sel1_o according to the second delay signal sel1_o. In this embodiment, when the second delay signal sel1_o is at the first level, e.g. the high logic level, multiplexer 620 outputs the first delay signal sel1_delay to OR gate 212. When the second delay signal sel1_o is at the second level, e.g. the low logic level, multiplexer 620 outputs the second delay signal sel1_o to OR gate 212.

FIG. 6b is a schematic diagram of another exemplary embodiment of the delay module. Delay module 610 comprises flip-flops 611˜614 and AND gate 615. Flip-flop 611 selectively outputs the voltage signal Vdd according to clock signal ck1. Flip-flop 612 selectively outputs the voltage signal Vdd according to the inversed clock signal ck1b inverse to clock signal ck1. Flip-flop 613 selectively outputs selected enable signal sel1_en to generate the second delay signal sel1_o according to the output signal ck_out. Flip-flop 614 generates synchronization signal sel1_sync by selectively outputting the second delay signal sel1_o according to an inversed output signal ck_outb. The output signal ck_out and the inversed output signal ck_outb are inverse. The synchronization signal sel1_sync is provided for resetting flip-flops 611 and 612. AND gate 615 generates the first delay signal sel1_delay according to the outputs of flip-flops 611 and 612.

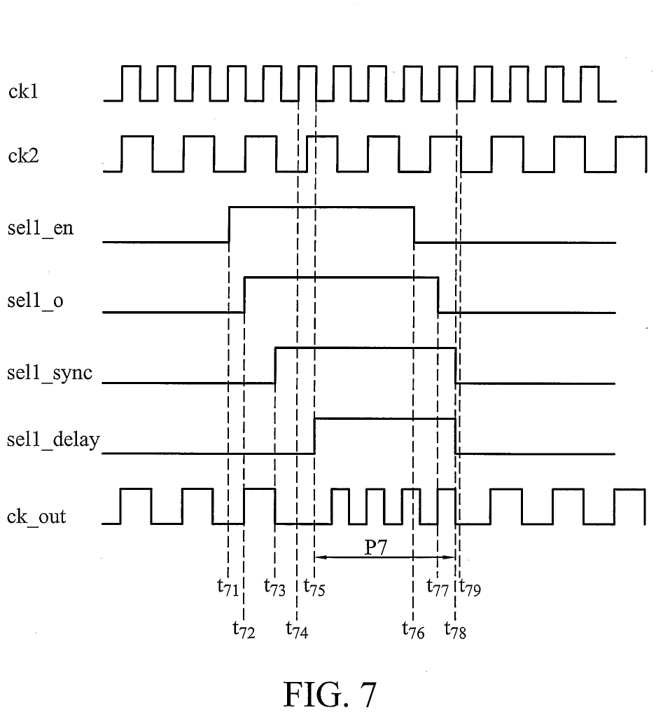

Since delay module 610 is similar to delay module 310 shown in FIG. 3a, only the second delay signal sel1_o is described. FIG. 7 is a timing chart of signals of delay module 610. Reference with FIG. 6b, selected enable signal sel1_en is changed from the low logic level to the high logic level at time point t₇₁. At time point t₇₂, output signal ck_out is changed from the low logic level to the high logic level such that flip-flop 613 is triggered. Thus, the second delay signal sel1_o is changed from the low logic level to the high logic level at time point t₇₂.

At time point t₇₃, inversed output signal ck_outb, which is inverse to output signal ck_out, is changed from the low logic level to the high logic level such that synchronization signal sel1_sync is changed from the low logic level to the high logic level. At time point t₇₄, clock signal ck1 is changed from the low logic level to the high logic level so as to trigger flip-flop 611. Since flip-flop 612 does not be triggered at time point t₇₄, the first delay signal sel1_delay is at the low logic level. At time point t₇₅, inversed clock signal ck1b, which is inverse to clock signal ck1, is changed from the low logic level to the high logic level so as to trigger flip-flop 612. Thus, the first delay signal sel1_delay is changed from the low logic level to the high logic level. During period P7, the first delay signal sel1_delay is at the high logic level, and the output signal ck_out approximately equals to clock signal ck1.

At time point t₇₆, selected enable signal sel1_en is changed from the high logic level to the low logic level. At time point t₇₇, output signal ck_out is changed from the low logic level to the high logic level such that flip-flop 613 is triggered. Thus, according to selected enable signal sel1_en at the low logic level, the second delay signal sel1_o is changed from the high logic level to the low logic level. Since the second delay signal sel1_o shown in FIG. 6b and selected enable signal sel1_en shown in FIG. 3b have the same principle, description of the second delay signal sel1_o is omitted for brevity.

At time point t₇₈, the inversed output signal ck_outb, which is inverse to output signal ck_out, is changed from the low logic level to the high logic level such that synchronization signal sel1_sync is changed from the high logic level to the low logic level. Thus, flip-flops 611 and 612 are reset such that the first delay signal sel1_delay is changed from the high logic level to the low logic level. At time point t₇₉, if the delay signal sel2_delay (not shown) is changed from the low logic level to the high logic level, the output signal ck_out is approximately equal to clock signal ck2.

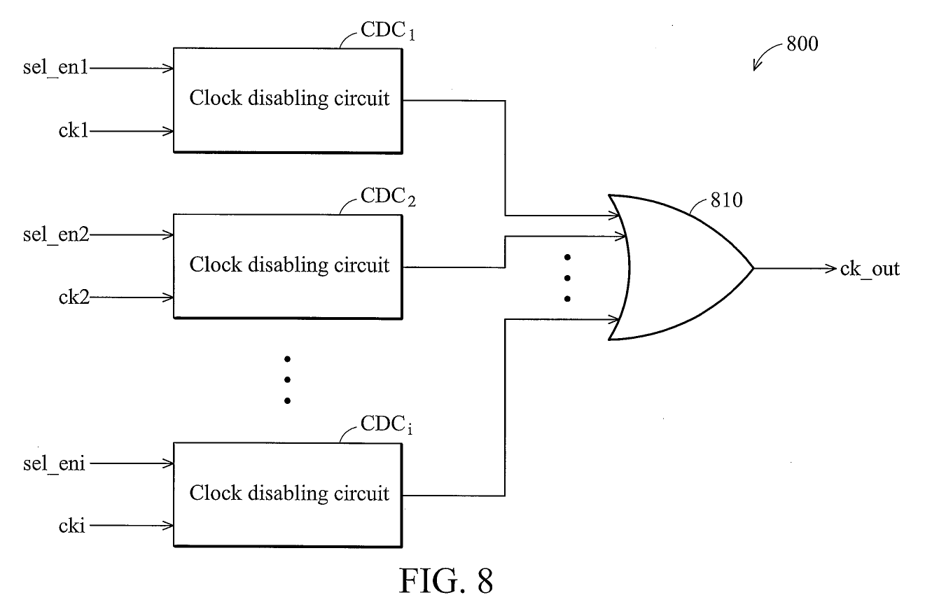

FIG. 8 is a schematic diagram of an exemplary embodiment of a clock switching circuit. The clock switching circuit 800 comprises clock disabling circuits CDC₁˜CDC₁ and an OR gate 810. The clock switching circuit 800 outputs an output signal ck_out according to selected enable signals sel_en1˜sel_eni. For example, when the selected enable signals sel_en1 is at a high logic level, the clock signal ck1 is typically served as the output signal ck_out. The selected enable signals sel_en1˜sel_eni are none-overlapping. In this embodiment, if one of selected enable signals sel_en1˜sel_eni is at a high logic level, the other selected enable signals are at a low logic level.

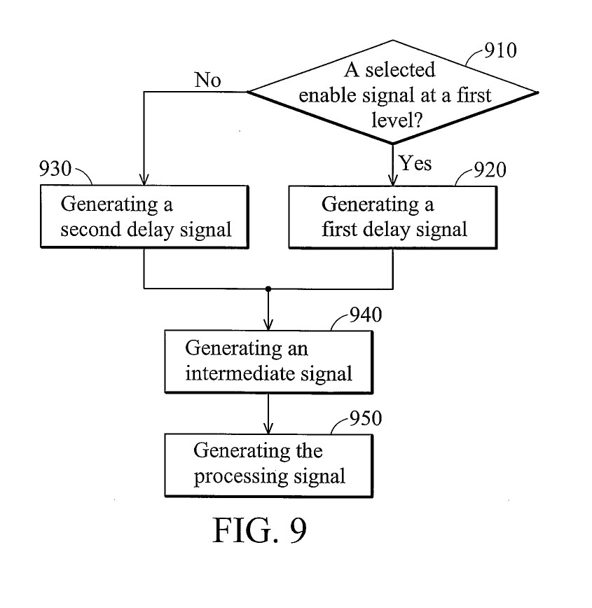

FIG. 9 is a flowchart of an exemplary embodiment of a clock disabling method. The following description is made with reference to FIGS. 2 and 9. It is determined whether a selected enable signal sel1_en is at a first level (step 910). If the selected enable signal sel1_en is at the first level, a first delay signal is generated (step 920). In this embodiment, the first delay signal is generated by delaying the selected enable signal sel1_en. If the selected enable signal sel1_en is not at the first level, e.g. at a second level, a second delay signal is generated (step 930). Delays of the first delay signal and the second delay signal are different. In this embodiment, the second delay signal can be generated by delaying the selected enable signal sel1_en or by directly outputting the selected enable signal sel1_en.

An intermediate signal S_{I1} is generated according to a processing signal S_{P1} and one of the first and the second delay signals dependent on what level the selected enable signal sel1_en is at (step 940). For example, if the selected enable signal sel1_en is at the first level, the intermediate signal SI₁ is generated according to a processing signal S_{P1} and the first delay signal. Similarly, if the selected enable signal sel1_en is at the second level, the intermediate signal S_{I1} is generated according to a processing signal S_{P1} and the second delay signal. In this embodiment, the processing signal S_{P1} is generated according to the intermediate signal S_{I1} and a clock signal ck1 (step 950).

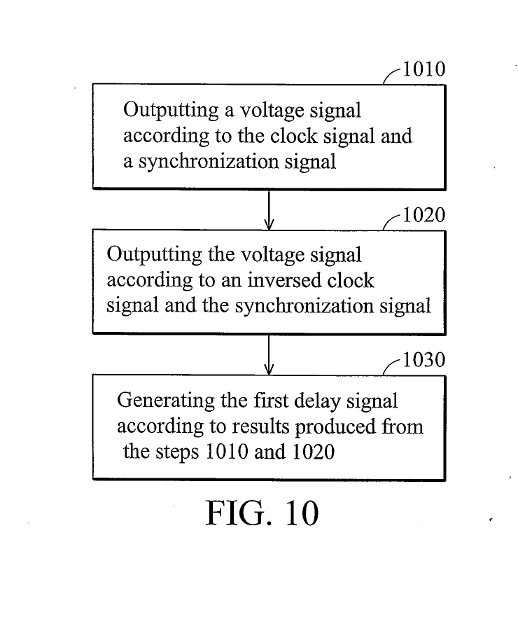

FIG. 10 is a flowchart of an exemplary embodiment of delaying the selected enable signal sel1_en. The following description is made with reference to FIGS. 3b and 10. A voltage signal Vdd is selectively output according to the clock signal ck1 and a synchronization signal sel1_syn (step 1010). In the step 1010 of this embodiment, the voltage signal Vdd is output when the clock signal ck1 is changed from a low logic level to a high logic level and the synchronization signal sel1_syn is at the high logic level, and the voltage signal Vdd is not output when the synchronization signal sel1_syn is at the low logic level.

The voltage signal Vdd is selectively output according to an inversed clock signal ck1b inverse to the clock signal ck1 and the synchronization signal sel1_syn (step 1020). In the step 1020 of this embodiment, the voltage signal Vdd is output when the inversed clock signal ck1b is changed from a low logic level to a high logic level and the synchronization signal sel1_syn is at the high logic level, and the voltage signal Vdd is not output when the synchronization signal sel1_syn is at the low logic level.

Then, the first or the second delay signal can be generated according to results produced from the steps 1010 and 1020 (step 1030). In this embodiment, the synchronization signal sel1_syn is generated by selectively outputting the selected enable signal sel1_en according to the inversed clock signal ck1b. For example, if the selected enable signal sel1_en is at the high logic level, the synchronization signal sel1_syn becomes at the high logic level when the inversed clock signal ck1b is changed from a low logic level to a high logic level. Similarly, if the selected enable signal sel1_en is at the low logic level, the synchronization signal sel1_syn keeps at the low logic level.

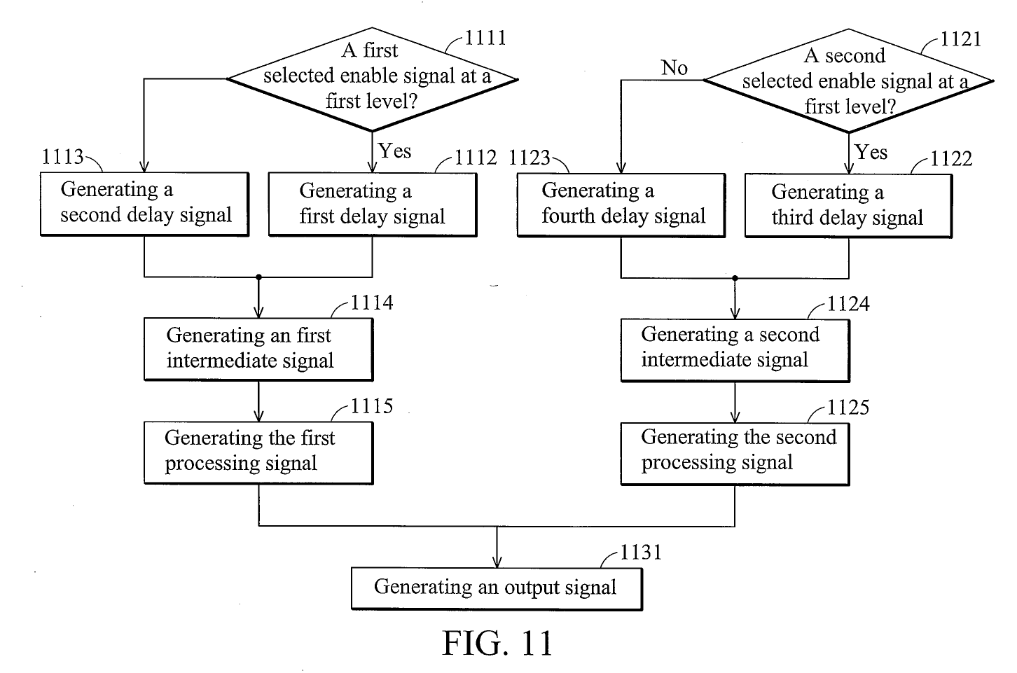

FIG. 11 is a flowchart of an exemplary embodiment of a clock switching method. The following description is made with reference to FIGS. 2 and 11. It is determined whether a first selected enable signal sel1_en is at a first level (step 1111). If the first selected enable signal sel1_en is at the first level, a first delay signal is generated (step 1112). In this embodiment, the first delay signal is generated by delaying the first selected enable signal sel1_en. If the first selected enable signal sel1_en is not at the first level, e.g. at a second level, a second delay signal is generated (step 1113). Delays of the first delay signal and the second delay signal are different. In this embodiment, the second delay signal is generated by delaying the first selected enable signal sel1_en or by directly outputting the first selected enable signal sel1_en.

A first intermediate signal S_{I1} is generated according to a first processing signal S_{P1} and one of the first and the second delay signals (step 1114). For example, if the first selected enable signal sel1_en is at the first level, the first intermediate signal S_{I1} is generated according to a first processing signal S_{P1} and the first delay signal. Similarly, if the first selected enable signal sel1_en is at the second level, the first intermediate signal S_{I1} is generated according to a first processing signal S_{P1} and the second delay signal. In this embodiment, the first processing signal S_{P1} is generated according to the first intermediate signal S_{I1} and a first clock signal ck1 (step 1115).

It is determined whether a second selected enable signal sel2_en is at a first level (step 1121). If the second selected enable signal sel2_en is at the first level, a third delay signal is generated (step 1122). In this embodiment, the third delay signal is generated by delaying the second selected enable signal sel12_en. If the second selected enable signal sel2_en is not at the first level, e.g. at a second level, a fourth delay signal is generated (step 1123). In this embodiment, the fourth delay signal is generated by delaying the second selected enable signal sel2_en or by directly outputting the second selected enable signal sel2_en. Delays of the third delay signal and the fourth delay signal are different. Moreover, in other embodiments, delay of the third delay signal is the same as or is different from that of the first delay signal.

A second intermediate signal S_{I2} is generated according to a second processing signal S_{P2} and one of the third and the fourth delay signals (step 1124). For example, if the second selected enable signal sel2_en is at the first level, the second intermediate signal S_{I2} is generated according to a second processing signal S_{P2} and the third delay signal. Similarly, if the second selected enable signal sel2_en is at the second level, the second intermediate signal S_{I2} is generated according to a second processing signal S_{P2} and the fourth delay signal. In this embodiment, the second processing signal S_{P2} is generated according to the second intermediate signal S_{I2} and a second clock signal ck2 (step 1125). An output signal ck_out is thus generated according to the first and the second processing signals S_{P1} and S_{P2} (step 1131).

In some embodiments, for example illustrated in FIG. 5, the first selected enable signal sel1_en can be generated according to an enable signal Sen and a first select signal sel1. The second selected enable signal sel2_en is generated according to the enable signal Sen and a second select signal sel2. The first and the second selected enable signals sel1_en and sel2_en are none-overlapping. For example, when the first selected enable signal sel1_en is at a high logic level, the second selected enable signal sel2_en is at a low logic level.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A clock disabling circuit, comprising:
a control unit for generating a first delay signal by delaying a selected enable signal when the selected enable signal is at a first level, and generating a second delay signal by delaying the selected enable signal or by directly outputting the selected enable signal when the selected enable signal is at a second level, wherein delays of the first delay signal and the second delay signal are different;
an OR gate for generating an intermediate signal according to an output of the control unit and a processing signal; and
a first AND gate for generating the processing signal according to the intermediate signal and a clock signal.

2. The clock disabling circuit as claimed in claim 1, wherein the first level is a high logic level and the second level is a low logic level.

3. The clock disabling circuit as claimed in claim 1, wherein the control unit comprises:
a delay module for delaying the selected enable signal to generate the first delay signal; and
a multiplexer for outputting one of the selected enable signal and the first delay signal according to the selected enable signal.

4. The clock disabling circuit as claimed in claim 3, wherein the delay module comprises:
a first flip-flop for selectively outputting a voltage signal according to the clock signal;
a second flip-flop for selectively outputting the voltage signal according to an inversed clock signal inverse to the clock signal;
a third flip-flop for generating a synchronization signal by selectively outputting the selected enable signal according to the inversed clock signal, wherein the synchronization signal is provided for resetting the first and the second flip-flops; and
a second AND gate for generating the first delay signal according to outputs of the first and the second flip-flops.

5. The clock disabling circuit as claimed in claim 1, wherein the control unit comprises:
a delay module for delaying the selected enable signal to generate the first and the second delay signals; and
a multiplexer for outputting one of the first delay signal and the second delay signal according to the second delay signal.

6. The clock disabling circuit as claimed in claim 5, wherein the delay module comprises:
a first flip-flop for selectively outputting a voltage signal according to the clock signal;
a second flip-flop for selectively outputting the voltage signal according to an inversed clock signal inverse to the clock signal;
a third flip-flop for selectively outputting the selected enable signal to generate the second delay signal according to an output signal based on the processing signal;
a fourth flip-flop for generating a synchronization signal by selectively outputting the second delay signal according to an inversed output signal inverse to the output signal, wherein the synchronization signal is provided for resetting the first and the second flip-flops; and
a second AND gate for generating the first delay signal according to outputs of the first and the second flip-flops.

7. A clock switching device, comprising:
a first clock disabling circuit comprising:
a first control unit for generating a first delay signal by delaying a first selected enable signal when the first selected enable signal is at a first level, and generating a second delay signal by delaying the first selected enable signal or by directly outputting the first selected enable signal when the first selected enable signal is at a second level, wherein delays of the first delay signal and the second delay signal are different;
a first OR gate for generating a first intermediate signal according to an output of the first control unit and a first processing signal; and
a first AND gate for generating the first processing signal according to the first intermediate signal and a first clock signal; and
a second clock disabling circuit comprising:
a second control unit for generating a third delay signal by delaying a second selected enable signal when the second selected enable signal is at the first level, and generating a fourth delay signal by delaying the second selected enable signal or by directly outputting the second selected enable signal when the second selected enable signal is at the second level, wherein delays of the third delay signal and the fourth delay signal are different;
a second OR gate for generating a second intermediate signal according to an output of the second control unit and a second processing signal; and
a second AND gate for generating the second processing signal according to the second intermediate signal and a second clock signal; and
a third OR gate receiving the first and the second processing signals to generate an output signal.

8. The clock switching device as claimed in claim 7, wherein the first level is a high logic level and the second level is a low logic level.

9. The clock switching device as claimed in claim 7, wherein the first control unit comprises:
a delay module for delaying the first selected enable signal to generate the first delay signal; and
a multiplexer for outputting one of the first selected enable signal and the first delay signal according to the first selected enable signal.

10. The clock switching device as claimed in claim 9, wherein the delay module comprises:
a first flip-flop for selectively outputting a voltage signal according to the first clock signal;
a second flip-flop for selectively outputting the voltage signal according to an inversed first clock signal inverse to the first clock signal;
a third flip-flop for generating a synchronization signal by selectively outputting the first selected enable signal according to the inversed first clock signal, wherein the synchronization signal is provided for resetting the first and the second flip-flops; and
a second AND gate for generating the first delay signal according to outputs of the first and the second flip-flops.

11. The clock switching device as claimed in claim 7, wherein the first control unit comprises:
a delay module for delaying the first selected enable signal to generate the first and the second delay signals; and
a multiplexer for outputting one of the first delay signal and the second delay signal according to the second delay signal.

12. The clock switching device as claimed in claim 11, wherein the delay module comprises:
a first flip-flop for selectively outputting a voltage signal according to the first clock signal;
a second flip-flop for selectively outputting the voltage signal according to an inversed first clock signal inverse to the first clock signal;
a third flip-flop for selectively outputting the first selected enable signal to generate the second delay signal according to the output signal;
a fourth flip-flop for generating a synchronization signal by selectively outputting the second delay signal according to an inversed first output signal inverse to the first output signal, wherein the synchronization signal is provided for resetting the first and the second flip-flops; and
a second AND gate for generating the first delay signal according to outputs of the first and the second flip-flops.

13. The clock switching device as claimed in claim 7, wherein the first and the second selected enable signals are inverse.

14. The clock switching device as claimed in claim 7, further comprising:
a first enable unit for generating the first selected enable signal according to an enable signal and a first select signal; and
a second enable unit for generating the second selected enable signal according to the enable signal and a second select signal.

15. A clock disabling method, comprising:
generating a first delay signal by delaying a selected enable signal when the selected enable signal is at a first level;
generating a second delay signal by delaying the selected enable signal or by directly outputting the selected enable signal when the selected enable signal is at a second level, wherein delays of the first delay signal and the second delay signal are different;
generating an intermediate signal according to a processing signal and a result produced from the steps of generating a first delay signal and a second delay signal; and
generating the processing signal according to the intermediate signal and a clock signal.

16. The clock disabling method as claimed in claim 15, wherein the step of delaying the selected enable signal comprises:
selectively outputting a voltage signal according to the clock signal;
selectively outputting the voltage signal according to an inversed clock signal inverse to the clock signal;
generating a synchronization signal by selectively outputting the selected enable signal according to the inversed clock signal, wherein the synchronization signal is provided for resetting the steps of selectively outputting the voltage signal; and
generating the first delay signal according to results produced from the steps of selectively outputting the voltage signal.

17. A clock switching method, comprising:
generating a first delay signal by delaying a first selected enable signal when the first selected enable signal is at a first level;
generating a second delay signal by delaying the first selected enable signal or by directly outputting the first selected enable signal when the first selected enable signal is at a second level, wherein delays of the first delay signal and the second delay signal are different;
generating a first intermediate signal according to a first processing signal and a result produced from the steps of generating a first delay signal and a second delay signal;
generating the first processing signal according to the first intermediate signal and a first clock signal;
generating a third delay signal by delaying a second selected enable signal when the second selected enable signal is at the first level;
generating a fourth delay signal by delaying the second selected enable signal or by directly outputting the second selected enable signal when the second selected enable signal is at the second level, wherein delays of the third delay signal and the fourth delay signal are different;
generating a second intermediate signal according to a second processing signal and a result produced from the steps of generating a third delay signal and a fourth delay signal;
generating the second processing signal according to the second intermediate signal and a second clock signal; and
generating an output signal according to the first processing signal and the second processing signal.

18. The clock switching method as claimed in claim 17, wherein the step of delaying the first selected enable signal comprises:
selectively outputting a voltage signal according to the first clock signal and a synchronization signal;
selectively outputting the voltage signal according to the synchronization signal and an inversed clock signal inverse to the first clock signal; and
generating the first delay signal according to results produced from the steps of selectively outputting the voltage signal.

19. The clock switching method as claimed in claim 19, further comprising:
selectively outputting the first selected enable signal according to the inversed clock signal for generating the synchronization signal, wherein the synchronization signal is provided for resetting the steps of selectively outputting the voltage signal.

20. The clock switching method as claimed in claim 17, wherein the first selected enable signal is generated according to an enable signal and a first select signal, and the second selected enable signal is generated according to the enable signal and a second select signal.
